(19) United States
(12) Patent Application Publication
(10) Pub. No.: US 2025/0157836 A1
(43) Pub. Date: May 15, 2025

(54) SUBSTRATE PROCESSING APPARATUS, SUBSTRATE PROCESSING SYSTEM, AND SUBSTRATE PROCESSING METHOD

(71) Applicant: SCREEN Holdings Co., Ltd., Kyoto (JP)

(72) Inventor: Shinji SHIMIZU, Kyoto (JP)

(21) Appl. No.: 18/839,544

(22) PCT Filed: Feb. 24, 2023
(86) PCT No.: PCT/JP2023/006687

§ 371 Date: Aug. 19, 2024

(30) Foreign Application Priority Data
Mar. 1, 2022 (JP) 2022-030897

(51) Int. Cl. H01L 21/67; H01L 21/66

(52) U.S. Cl. CPC H01L 21/67288; H01L 21/67023; H01L 22/12

(57) ABSTRACT

When processing is performed on a substrate according to a recipe in a housing, a control unit causes a camera to acquire an adjusted photographed image. The abnormality detection unit detects an abnormality of a target component based on the adjusted photographed image. The adjusted photographed image can be an image suitable for abnormality detection for each target component because the photographing condition is adjusted for each target component according to the process of the recipe. Therefore, the abnormality can be accurately detected regardless of the process of the recipe.

### TECHNICAL FIELD

The present invention relates to a substrate processing apparatus, a substrate processing system, and a substrate processing method for performing predetermined processing on a substrate such as a semiconductor substrate, a substrate for a flat panel display (FPD) such as a liquid crystal display or an organic electroluminescence (EL) display device, a glass substrate for a photomask, or a substrate for an optical disk, and particularly relates to a technique for detecting an operation state of a component constituting the device.

### BACKGROUND ART

Conventionally, as this type of a first device, there is a device including a drive arm, a main control unit, a monitoring unit, a camera, and an image processing unit (see, for example, Patent Literature 1).

The drive arm includes a nozzle at a tip portion. The drive arm moves a nozzle for supplying the treatment liquid above the substrate. The main control unit controls the drive arm. The main control unit has first nozzle position information as information indicating the position of the nozzle. The monitoring unit receives the first nozzle position information. The image processing unit receives an image from a camera with a fixed position. The image processing unit provides the monitoring unit with second nozzle position information indicating the arrangement position of the nozzle from the position information of a liquid column image. The monitoring unit compares the first nozzle position information with the second nozzle position information to monitor an abnormality in the position of the nozzle.

In addition, as this type of a second device, there is a device including a spin chuck, a chuck, a camera, and a control unit (see, for example, Patent Literature 2).

A chuck is provided on the outer peripheral side of the spin chuck. The spin chuck holds the outer peripheral edge of the substrate with the chuck. The camera is fixed to a casing that houses the spin chuck. In the camera, the direction of the lens is set so as to capture an image of the peripheral edge portion of the substrate. The camera captures images of the substrate and the chuck. The camera has a zoom function and can capture an image of the chuck in an enlarged manner. The control unit detects an abnormality in the holding state of the substrate based on the image captured by the camera.

### CITATION LIST

### Patent Literature

Patent Literature 1: WO 2019/146456 B1
Patent Literature 2: JP 2013-110270 A

### SUMMARY OF INVENTION

### Technical Problem

However, the conventional example having such a configuration has the following problems.

That is, in the conventional first device, the nozzle is imaged small depending on the positional relationship between the nozzle and the camera. Therefore, in the captured image, there is a possibility that a resolution sufficient for determining an abnormality of the nozzle cannot be obtained. As a result, an abnormality may not be accurately detected. In order to overcome this problem, it is conceivable to use a high-resolution camera, but this is not realistic because the capacity of image data becomes too large and the load of image processing increases.

In addition, the conventional second device can accurately detect an abnormality related to the holding state of the substrate from the photographed image enlarged by the camera zoom function. However, depending on the process of the recipe, it is necessary to perform abnormality detection of another portion different from the substrate holder. However, since the camera is fixed to the casing, an appropriate image cannot be captured only by the zoom function. Therefore, there is a problem that an abnormality cannot be accurately detected depending on the process of the recipe.

The present invention has been made in view of such circumstances, and an object thereof is to provide a substrate processing apparatus, a substrate processing system, and a substrate processing method capable of accurately detecting an abnormality regardless of a process of a recipe.

### Solution to Problem

In order to achieve such an object, the present invention has the following configuration.

That is, the invention according to claim 1 is a substrate processing apparatus that performs predetermined processing on a substrate, the substrate processing apparatus including: a processing unit configured to process a substrate; a photographing unit configured to image a target component that is an abnormality detection target among components constituting the processing unit, the photographing unit being capable of adjusting photographing conditions of a photographing direction of panning for moving a photographing field of view in a horizontal direction and tilting for moving a photographing field of view in a vertical direction, and a photographing magnification of zooming for expanding and contracting a photographing field of view; a control unit configured to, when processing is performed by the processing unit according to a recipe defining processing contents of a substrate, cause the photographing unit to capture an image by adjusting the photographing condition for each target component according to a process of the recipe, and cause the photographing unit to acquire an adjusted photographed image; and an abnormality detection unit configured to detect an abnormality of the target component based on the adjusted photographed image.

[Operation and Effect] According to the invention described in claim 1, when the processing unit performs processing on the substrate according to the recipe, the control unit causes the photographing unit to acquire the adjusted photographed image. The abnormality detection unit detects an abnormality of a target component based on the adjusted photographed image. The adjusted photographed image can be an image suitable for abnormality detection for each target component because the photographing condition is adjusted for each target component according to the process of the recipe. Therefore, the abnormality can be accurately detected regardless of the process of the recipe.

In addition, in the present invention, it is preferable to further include a photographing condition storage unit configured to store the photographing condition in advance for each process of the recipe. The control unit causes photographing to be performed based on the photographing condition (claim 2).

Since the photographing condition is stored in advance in the photographing condition storage unit, the control unit can reliably adjust the photographing condition on the basis of the photographing condition.

In addition, in the present invention, it is preferable to further include a recognition unit configured to recognize a specific target component projected in a photographed image captured by the photographing unit. The control unit adjusts the photographing direction in such a way to track the specific target component according to a recognition result of the recognition unit (claim 3).

Since the moving target component is tracked, the change in the photographing direction of the photographing unit can be minimized when photographing is performed at the destination. Therefore, in the case of the moving target component, it is possible to prevent the photographing at the movement destination from being delayed.

In addition, in the present invention, in the photographing condition, the photographing magnification is preferably set to a maximum magnification so as to minimize the photographing field of view in a case where a plurality of the target components falls within a photographing field of view of the photographing unit (claim 4).

Since the photographing magnification is the maximum, even in a case where a plurality of target components are imaged as described above, a resolution sufficient for abnormality detection can be obtained for each target component.

In addition, in the present invention, it is preferable to further include a mirror disposed at a position facing the photographing unit and facing the photographing unit, and configured to reflect the target component in a blind spot from the photographing unit toward the photographing unit. The photographing unit captures an image of the target component in a blind spot via the mirror (claim 5).

The photographing unit can capture an image of the target component in a blind spot via the mirror. Therefore, the abnormality of the target component in a blind spot can be detected without increasing the number of the photographing units. As a result, the device cost can be suppressed.

In addition, in the present invention, it is preferable to include a plurality of the substrate processing apparatuses according to any one of the above (claim 5).

Even in a substrate processing system including a plurality of substrate processing apparatuses, an abnormality can be accurately detected during operation.

### Advantageous Effects of Invention

According to the substrate processing apparatus of the present invention, when the processing unit performs processing on the substrate according to the recipe, the control unit causes the photographing unit to acquire the adjusted photographed image. The abnormality detection unit detects an abnormality of a target component based on the adjusted photographed image. The adjusted photographed image can be an image suitable for abnormality detection for each target component because the photographing condition is adjusted for each target component according to the process of the recipe. Therefore, the abnormality can be accurately detected regardless of the process of the recipe.

### BRIEF DESCRIPTION OF DRAWINGS

FIG. 1 is a side view illustrating a substrate processing apparatus according to an embodiment.

FIG. 2 is a plan view of the substrate processing apparatus according to the embodiment.

FIG. 3 is a block diagram of the substrate processing apparatus according to the embodiment.

FIG. 4 is a schematic view for explaining photographing conditions in origin position confirmation.

FIG. 5 is a schematic view for explaining photographing conditions in delivery confirmation and guard confirmation.

FIG. 6 is a schematic view for explaining photographing conditions in nozzle movement.

FIG. 7 is a schematic view illustrating an example of a recipe.

FIG. 8 is a flowchart illustrating a flow of processing in the substrate processing apparatus according to the embodiment.

FIG. 9 is a schematic view for explaining another photographing condition.

FIG. 10 is a schematic view for explaining photographing conditions in a case where a mirror is used.

FIG. 11 is a schematic view of a substrate processing system according to an embodiment.

### DESCRIPTION OF EMBODIMENTS

Hereinafter, an embodiment of the present invention will be described with reference to the drawings.

### <1. Overall Configuration>

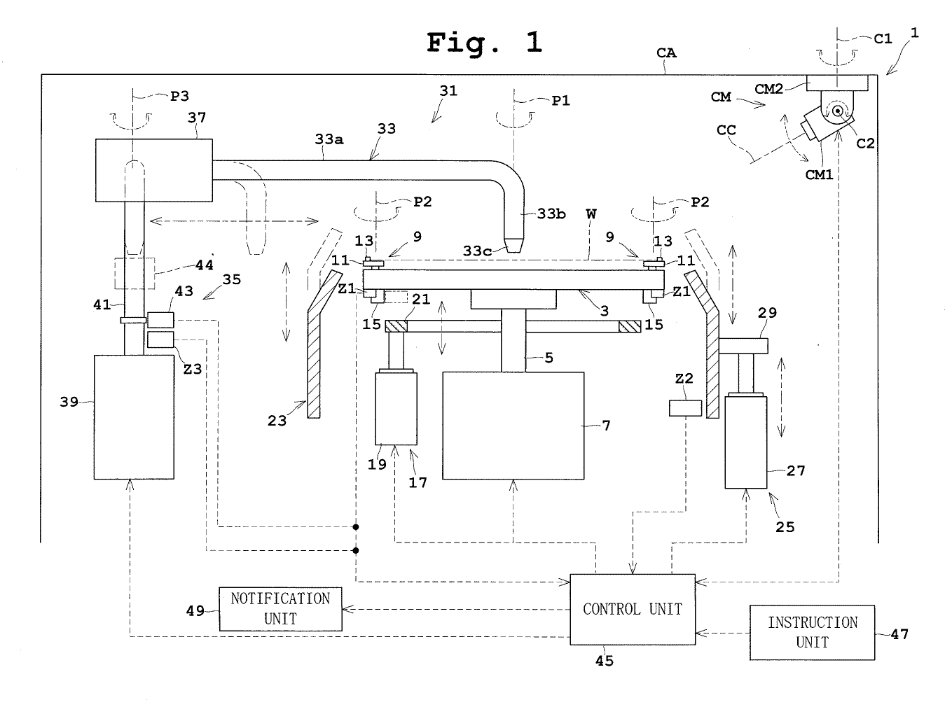

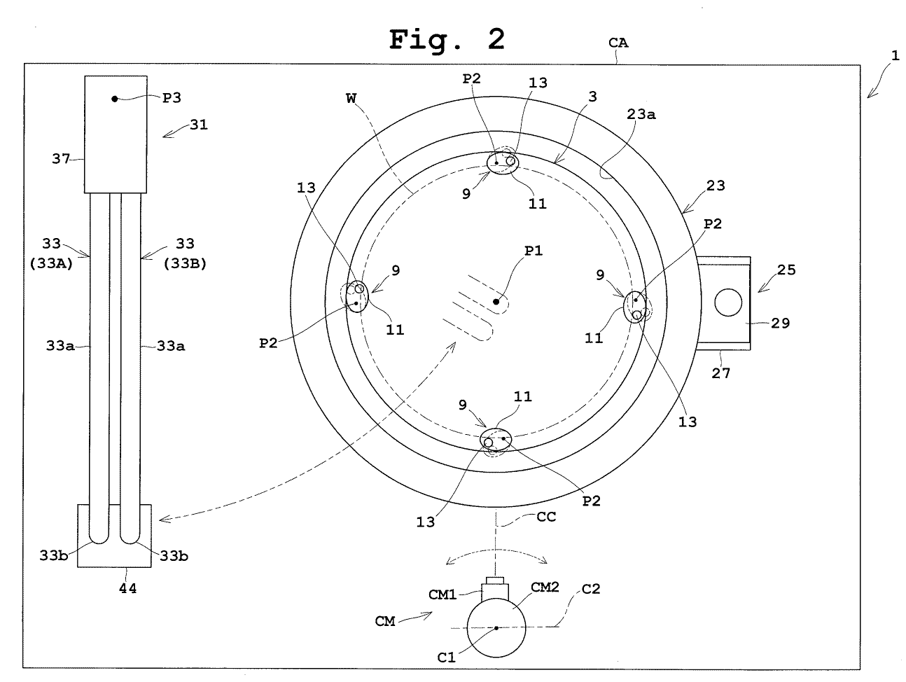

FIG. 1 is a side view illustrating a substrate processing apparatus according to an embodiment. FIG. 2 is a plan view of the substrate processing apparatus according to the embodiment.

A substrate processing apparatus 1 is a single wafer type apparatus that processes substrates W one by one. The substrate W has, for example, a circular shape in plan view. The substrate processing apparatus 1 supplies a treatment liquid to the substrate W while rotating the substrate W to perform predetermined processing on the substrate W.

The substrate processing apparatus 1 includes a housing CA. The housing CA shields the inside from the ambient atmosphere. The substrate processing apparatus 1 includes a spin chuck 3. The spin chuck 3 has a circular shape having a diameter larger than that of the substrate W in plan view. The upper end of a rotation shaft 5 is connected to the lower surface of the spin chuck 3. The lower end of the rotation shaft 5 is connected to a motor 7. When the motor 7 is driven, the spin chuck 3 is rotated around a rotation center P1. The rotation center P1 extends in the vertical direction.

The spin chuck 3 includes a plurality of chucks 9. The spin chuck 3 includes a plurality of spin chucks 9 on the peripheral edge portion of the upper surface. In the present embodiment, the spin chuck 3 includes four chucks 9. As long as the substrate W can be stably rotated around the rotation center P1 while being supported in a horizontal posture, the number of chucks 9 is not limited to four.

The chuck 9 includes a lower surface support portion 11 and a peripheral edge support portion 13. The lower surface support portion 11 abuts and supports the lower surface of the substrate W. The lower surface support portion 11 is preferably configured such that a contact area with the lower surface of the substrate W is reduced. In this way, the degree of mutual contamination can be reduced. The lower surface support portion 11 is rotatably attached to the upper surface of the spin chuck 3 at a rotation center P2. The rotation center P2 extends in the vertical direction. The peripheral edge support portion 13 is erected on the upper surface of the lower surface support portion 11. The peripheral edge support portion 13 is preferably formed such that the height from the upper surface of the lower surface support portion 11 is larger than the thickness of the substrate W. With such a configuration, the peripheral edge of the substrate W can be stably held. The peripheral edge support portion 13 is provided at a position away from the rotation center P2 toward the outer edge of the lower surface support portion 11 in plan view. In other words, the peripheral edge support portion 13 is eccentric from the rotation center P2.

A rotating magnet 15 is attached to the lower surface of the spin chuck 3 at a position corresponding to the rotation center P2. The rotating magnet 15 is connected to the lower surface support portion 11. The rotating magnet 15 is rotatably provided around the rotation center P2. A chuck drive mechanism 17 is disposed below the rotating magnet 15.

The chuck drive mechanism 17 is disposed closer to the rotation shaft 5 than the chuck 9. The chuck drive mechanism 17 includes, for example, an air cylinder 19 and a driving magnet 21. The driving magnet 21 has an annular shape in plan view. The air cylinder 19 is disposed in a posture in which the operation shaft is oriented in the vertical direction. The driving magnet 21 is attached to the distal end of the operation shaft of the air cylinder 19. The chuck drive mechanism 17 is operated in accordance with a chuck operation command. When the chuck drive mechanism 17 is operated, the driving magnet 21 moves up and approaches the chuck 9, and when the chuck drive mechanism is not operated, the driving magnet 21 moves down and separates from the chuck 9.

The chuck 9 includes a biasing mechanism (not illustrated). When the driving magnet 21 moves down, the chuck 9 is at the closing position. The chuck 9 is in the open position when the driving magnet 21 moves up. At the closing position, the peripheral edge support portion 13 rotates around the rotation center P2, and the peripheral edge support portion 13 approaches the rotation center P1 side and abuts on the peripheral edge of the substrate W. As a result, the chuck 9 can hold the substrate W at the closing position. At the open position, the peripheral edge support portion 13 rotates about the rotation center P2, and the peripheral edge support portion 13 moves in a direction away from the rotation center P1. As a result, the chuck 9 can load and unload the substrate W at the open position. When the driving magnet 21 moves down in a state where the substrate W is not placed, the peripheral edge support portion 13 is at the origin position moved slightly inward from the outer diameter of the substrate W. In other words, at the origin position of the chuck 9, the peripheral edge support portion 13 is positioned closer to the rotation center P1 than the closing position.

An origin sensor Z1 is disposed near the rotating magnet 15 of the chuck 9. The output signal of the origin sensor Z1 changes when the chuck 9 moves to the closing position or the origin position. For example, when the chuck 9 moves to the closing position or the origin position, the output signal of the origin sensor Z1 is turned on.

A guard 23 is disposed around the spin chuck 3. The guard 23 surrounds the side of the spin chuck 3. The guard 23 prevents the treatment liquid from scattering around. The guard 23 has a tubular shape. An opening 23a is formed in an upper portion of the guard 23. The inner diameter of the opening 23a is larger than the outer shape of the spin chuck 3.

The guard 23 includes a guard moving mechanism 25. The guard moving mechanism 25 includes, for example, an air cylinder 27 and a locking piece 29. The guard moving mechanism 25 is disposed, for example, on the outer peripheral side of the guard 23. The guard moving mechanism 25 may be disposed on the inner peripheral side of the guard 23 as long as the guard 23 can move up and down. The air cylinder 27 is disposed in a posture in which the operation shaft is oriented in the vertical direction. The locking piece 29 is attached to the distal end of the operation shaft of the air cylinder 27. The locking piece 29 is fixed to the outer peripheral surface of the guard 23. The guard moving mechanism 25 is not limited to such a configuration as long as the guard 23 can move up and down.

The guard moving mechanism 25 moves the guard 23 between the origin position and the processing position in response to a guard operation command. The origin position is a position where the upper end of the guard 23 is low. The origin position is a position lower than the processing position. The processing position is a position higher than the origin position. In a state where the guard 23 is located at the origin position, the upper edge of the guard 23 is lower than the substrate W supported by the spin chuck 3. In a state where the guard 23 is located at the processing position, the upper edge of the guard 23 is higher than the substrate W supported by the spin chuck 3. For example, an origin sensor Z2 is disposed on the inner peripheral side of the guard 23. When the guard 23 moves to the origin position, the output signal of the origin sensor Z2 changes. For example, when the guard 23 moves to the origin position, the output signal of the origin sensor Z2 is turned on.

The guard 23 includes a plurality of drainage ports (not illustrated) on the inner peripheral side. The guard 23 preferably includes a plurality of guards 23 so as to move up and down by the guard moving mechanism 25 to perform switching to each of the drainage ports. In this case, the drainage port is switched according to the treatment liquid, and the guard moving mechanism 25 moves the height of the guard 23 accordingly.

A treatment liquid supply mechanism 31 is disposed on the outer peripheral side of the guard 23. The treatment liquid supply mechanism 31 includes, for example, a nozzle 33 and a nozzle moving mechanism 35. In the present embodiment, the treatment liquid supply mechanism 31 includes, for example, two nozzles 33. In the following description, in a case where it is necessary to distinguish the two nozzles 33, the left side in FIG. 2 is appropriately referred to as a nozzle 33A, and the right side is referred to as a nozzle 33B. The treatment liquid supply mechanism 31 may have one or three or more nozzles 33. In the present embodiment, it is assumed that the two nozzles 33 have the same configuration.

The nozzle 33 includes an extending portion 33a, a hanging portion 33b, and a tip portion 33c. One end side of the extending portion 33a of the nozzle 33 is attached to a base portion 37. The extending portion 33a extends in the horizontal direction. The other end side of the extending portion 33a is connected to the hanging portion 33b. The hanging portion 33b extends downward in the vertical direction from the extending portion 33a. The tip portion 33c forms a lower end portion of the hanging portion 33b. The tip portion 33c discharges the treatment liquid from the lower surface. Examples of the treatment liquid include a photoresist liquid, a spin-on-glass (SOG) liquid, a developer, a rinse liquid, pure water, and a cleaning liquid.

The nozzle moving mechanism 35 includes, for example, a motor 39, a rotation shaft 41, and a position detection unit 43. The motor 39 is disposed in a vertical posture. The rotation shaft 41 is rotated around a rotation center P3 by the motor 39. The rotation shaft 41 is connected to the base portion 37. The base portion 37 is rotated by driving of the motor 39. The nozzle 33 is swung around the rotation center P3 together with the base portion 37. The position detection unit 43 detects the rotational position of the rotation shaft 41. The position detection unit 43 detects an angle around the rotation center P3 of the rotation shaft 41 in plan view. The position detection unit 43 outputs a pulse according to the rotational position.

A standby cup 44 is disposed at a position laterally away from the guard 23 in plan view. The standby cup 44 is disposed on the side opposite to the base portion 37 and on the tip portion 33c side of the nozzle 33 in plan view. The standby cup 44 is disposed at the origin position of the nozzle 33. The standby cup 44 prevents the tip portion 33c of the nozzle 33 from drying. The standby cup 44 is used for idle discharge of the nozzle 33. The nozzle moving mechanism 35 drives the motor 39 to swing and drive the nozzle 33. The nozzle moving mechanism 35 moves the tip portion 33c between the origin position and a discharge position above the rotation center P1 of the spin chuck 3.

For example, an origin sensor Z3 is disposed on the outer peripheral portion of the rotation shaft 41. The output signal of the origin sensor Z3 changes when the nozzle 33 is located at the origin position. For example, when the nozzle 33 moves to the origin position, the output signal of the origin sensor Z3 is turned on. The origin sensor Z3 may be omitted to simplify the configuration. In this case, a projection is provided on a part of the rotation shaft 41, and a projection is also provided on the fixed side. The position detection unit 43 may detect that the rotation is not possible due to the abutment of the projections by the rotation of the rotation shaft 41 to set the origin position. In that case, a position at the time when the pulse of the position detection unit 43 becomes unchanged may be treated as the origin position.

A camera CM is attached to a part of the housing CA. For example, the camera CM is attached near the center of one side of the nozzle 33 on which the standby cup 44 is disposed in plan view. Specifically, the camera CM is attached to the ceiling surface of the housing CA. Due to this arrangement relationship, among the four chucks 9, the chuck 9 farthest from the camera CM is the smallest, the chuck 9 closest to the camera CM is the largest, and the two chucks 9 in the middle thereof are projected to a size approximately in the middle thereof. The arrangement position of the camera CM may be any position as long as a target component to be described later falls within the field of view. The lens of the camera CM has a viewing angle at which all components to be described later fall within the field of view.

The camera CM includes a camera body CM1 and a camera moving mechanism CM2. The camera CM can adjust the photographing direction by panning and tilting. The panning is to move the photographing field of view in the horizontal direction. The tilting is to move the photographing field of view in the vertical direction. The camera body CM1 includes zooming that changes a photographing magnification. The zooming is to enlarge or reduce a photographing field of view. There are an optical zooming and a digital zooming. The camera body CM1 includes an optical zooming. The optical type has an advantage that image degradation is less than that of the digital type even if the optical type is enlarged. Here, panning, tilting, and zooming are referred to as photographing conditions. The aspect ratio of the photographing field of view is fixed. The camera CM preferably always outputs images in the field of view under the latest photographing conditions at predetermined intervals for a tracking function to be described later. This is referred to as a real-time image.

The camera moving mechanism CM2 rotates the camera body CM1 around a rotation center C1 in the vertical direction. Specifically, the camera moving mechanism CM2 can swing the camera body CM1 in a range of about 180° in the horizontal direction around the rotation center C1. As a result, the photographing center CC of the camera body CM1 swings in a range of about 180° in the horizontal direction. The camera moving mechanism CM2 rotates the camera body CM1 about a rotation center C2 in the horizontal direction. Specifically, the camera moving mechanism CM2 can swing the camera body CM1 around the rotation center C2 in a range of about 90° in the vertical direction. As a result, the photographing center CC of the camera body CM1 swings in a range of about 90° in the vertical direction. The camera body CM1 can receive a signal from the outside and adjust the photographing conditions. The camera body CM1 and the camera moving mechanism CM2 are operated by a control unit 45 described later. The camera body CM1 includes an optical lens and a semiconductor imaging element. Examples of the semiconductor imaging element include a charge coupled device (CCD).

The substrate processing apparatus 1 includes a control unit 45, an instruction unit 47, and a notification unit 49. Details of the control unit 45 will be described later. The instruction unit 47 is operated by an operator of the substrate processing apparatus 1. The instruction unit 47 is, for example, a keyboard or a touch panel. The instruction unit 47 instructs a target component, a confirmation required timing, an allowable range, a recipe, start of processing, a photographing condition, and the like to be described later. In a case where it is determined that the control unit 45 is abnormal, the notification unit 49 notifies the operator of the abnormality. Examples of the notification unit 49 include a display, a lamp, and a speaker.

### <2. Configuration of Control System>

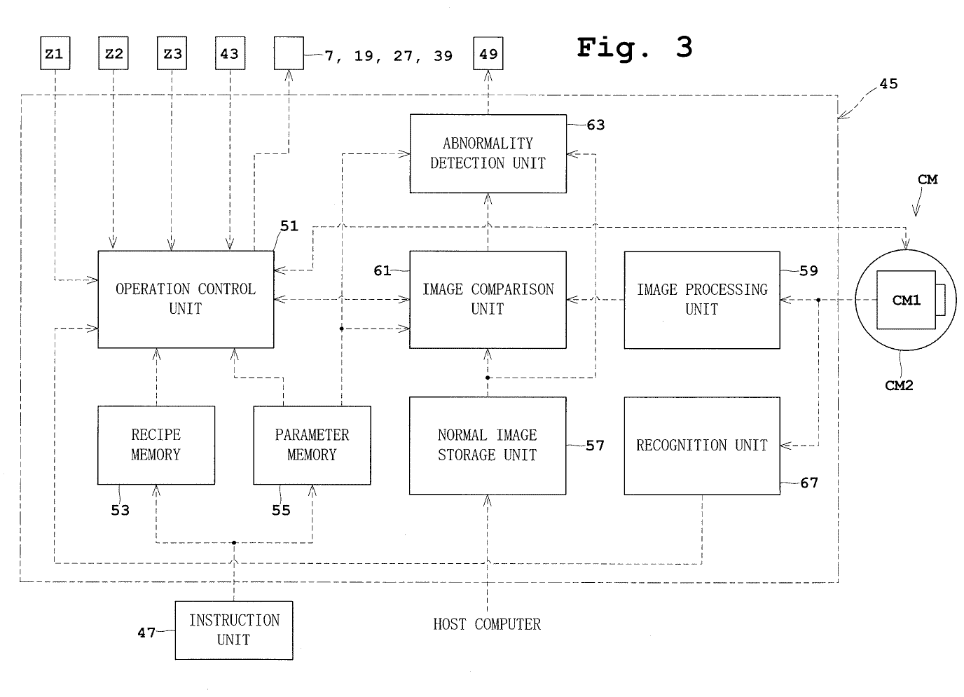

Reference is now made to FIG. 3. FIG. 3 is a block diagram of the substrate processing apparatus according to the embodiment.

The control unit 45 includes a CPU, a memory, and the like. The control unit 45 includes a plurality of functional blocks. Specifically, the control unit 45 includes an operation control unit 51, a recipe memory 53, a parameter memory 55, a normal image storage unit 57, an image processing unit 59, an image comparison unit 61, an abnormality detection unit 63, and a recognition unit 67.

The operation control unit 51 operates the motors 7 and 39, the air cylinders 19 and 27, and the camera CM. The operation control unit 51 receives signals from the origin sensors Z1 to Z3 and the position detection unit 43. The operation by the operation control unit 51 is performed according to the recipe defined in the recipe memory 53. For example, after a recipe and start of processing are instructed by the operator, the operation control unit 51 outputs various operation commands on the basis of the recipe to operate the motor 7 and the like at a predetermined timing. The operation control unit 51 operates the camera CM to perform photographing at a predetermined timing according to the recipe. The operation control unit 51 adjusts the photographing condition of the camera CM according to the recipe.

The recipe memory 53 stores various recipes in advance. The recipe defines various procedures for processing the substrate W. The recipe defines the operation content and execution order of the components, the execution timing, and the like. Specific examples of the recipe and details thereof will be described later. The operator can instruct a desired recipe by operating the instruction unit 47.

The parameter memory 55 stores a target component to be detected for an abnormal operation to be described later, confirmation required timing, an allowable range, and the like. The target component is an abnormality detection target among the elements constituting the substrate processing apparatus 1. The confirmation required timing is a timing for confirming the operation state of a component. The confirmation required timing is one time point on the time axis of the recipe to be described later. The confirmation required timing is synchronized with the execution of the recipe. The confirmation required timing corresponds to one normal image to be described later. The target component, the confirmation required timing, the allowable range, and the like can be arbitrarily set by the operator operating the instruction unit 47. The operator can issue an instruction from the instruction unit 47 as an allowable range such as which element is set as a target component to be detected for an abnormal operation, which timing is set as a confirmation required timing, and how much timing error or position error is allowed.

The parameter memory 55 stores the above-described photographing conditions in advance. The photographing condition can be set for each process of the recipe. The photographing condition can be set according to the confirmation required timing in the processing of the recipe and the target component. In a case where the confirmation required timing is not set, nothing is set as the photographing condition in the processing of the recipe. In a case where the photographing condition is not set, photographing by the camera CM is not performed.

The target component is, for example, the chuck 9, the guard 23, the nozzle 33, the treatment liquid, or the like. The confirmation required timing is, for example, a timing at which the chuck 9 is located at the origin position, a timing at which the chuck 9 is located at the closing position, a timing at which the guard 23 is located at the origin position, a timing at which the guard 23 is located at the processing position, a timing at which the nozzle 33 is located at the origin position, a timing from the origin position to the discharge position of the nozzle 33, and the like. The confirmation required timing is not limited thereto. Any timing desired to be set as an abnormality detection target can be set as the confirmation required timing.

The allowable range indicates an allowable degree of deviation of the position of the target component in the adjusted photographed image with respect to the position (normal image to be described later) where the target component should originally exist in the normal operation at the confirmation required timing. The allowable range is, for example, a degree indicating how much the target component allows a deviation from a position or angle intended by design. The allowable range indicates a range of deviation at the confirmation required timing of the target component in which the processing on the substrate W is allowable even if the target component deviates from the position or angle designed at the confirmation required timing with the processing on the substrate W as a reference.

The operation control unit 51 described above notifies the image comparison unit 61 and the camera CM of the confirmation required timing while executing the recipe on the basis of the confirmation required timing of the parameter memory 55. The operation control unit 51 adjusts the photographing condition for each target component and causes the camera CM to perform photographing.

The normal image storage unit 57 stores a normal image in advance. The normal image is, for example, a still image. The normal image is stored in association with confirmation required timing for each recipe stored in the recipe memory 53. The normal image is an image based on three-dimensional design information related to the assembly and operation of the substrate processing apparatus 1. On the basis of the three-dimensional design information of the substrate processing apparatus 1, a state in which the host computer normally operates according to a recipe is simulated in advance by a simulator, and at that time, the normal image is an image obtained from the viewpoint of the same arrangement position as the camera CM and under the same photographing condition. The normal image is an image obtained in association with the confirmation required timing on the time axis in the recipe. A plurality of confirmation required timings can be set during simulation. That is, a plurality of normal images can be provided in one recipe. The set confirmation required timing is associated with the recipe. The confirmation required timing is transferred from the host computer to the parameter memory 55. Specifically, the component design information is design information of components constituting the substrate processing apparatus 1 and the substrate W to be processed. The design information is, for example, three-dimensional computer aided design (3D CAD) data. The design information may include a treatment liquid used for treatment, physical property information on various materials, and the like.

The 3D CAD data is expressed by, for example, three axes whose coordinate axes are orthogonal to each other, and is expressed by position information of a position and an angle when a part is arranged in a three-dimensional space. A host computer (not illustrated) stores three-dimensional design information as 3D CAD data regarding all components and materials of the substrate processing apparatus 1. The simulator simulates the operation of the substrate processing apparatus 1. The simulator is executed by the host computer. The simulator is given three-dimensional design information of the substrate processing apparatus 1 and a recipe. The simulator can operate the substrate processing apparatus 1 according to the recipe. The simulator operates each component at a predetermined timing and in a predetermined order according to the definition of the recipe. In other words, the simulator can virtually normally operate the substrate processing apparatus 1 assembled according to the three-dimensional design information according to the recipe.

As the normal image described above, an image actually captured by the substrate processing apparatus 1 having the same configuration may be adopted instead of the image captured by the simulator. That is, when the normal operation according to the recipe is performed by the substrate processing apparatus 1 having the same configuration, an image captured by the camera CM may be adopted. The image is captured at the confirmation required timing and is captured under the same photographing condition.

The image processing unit 59 processes the adjusted photographed image photographed by the camera CM. The image processing unit 59 preferably performs image processing on the adjusted photographed image to extract an image including the two-dimensional shape of the target component. It is preferable that the image processing unit 59 perform, for example, contour extraction for all components shown in the adjusted photographed image. The contour here includes not only the contour of the outer shape but also an edge portion located inside the outer shape. The adjusted photographed image extracted by the image processing unit 59 is provided to the image comparison unit 61.

The image comparison unit 61 performs image comparison processing. Specifically, the comparison processing is performed between the adjusted photographed image extracted by the image processing unit 59 and the normal image. The normal image is an image given from the normal image storage unit 57. The normal image and the adjusted photographed image are synchronized with the execution of the recipe executed by the operation control unit 51. That is, when the recipe is executed in the simulator in advance, the normal image is captured at the confirmation required timing in the recipe and under the photographing condition for each target component. The adjusted photographed image is an image that the operation control unit 51 causes the camera CM to perform photographing according to the confirmation required timing from the parameter memory 53 associated with the recipe and under the photographing condition for each target component when the recipe is executed. The image comparison unit 61 compares the normal image with the adjusted photographed image, and specifies the target component in the adjusted photographed image and the target component in the actual image. With this specification, even in a case where a plurality of target components are present in the normal image and the adjusted photographed image, the same components can be compared with each other.

The abnormality detection unit 63 compares the normal image with the adjusted photographed image, and detects an abnormality based on a difference therebetween. The abnormality is detected in consideration of an allowable range of the parameter memory 55. In other words, the abnormality is not detected as long as it is within the allowable range even if the positions and the like of the target components displayed in the normal image and the adjusted photographed image do not exactly coincide with each other. The abnormality detection unit 63 causes the notification unit 49 to perform a notification operation according to the detection result. Specifically, the abnormality detection unit 63 causes the notification unit 49 to perform the notification operation only when an abnormality is detected. The notification unit 49 may also notify the target component determined to be abnormal and the degree of difference together with the occurrence of the abnormality, for example. In addition, the abnormality detection unit 63 preferably calculates the degree of difference as a score.

The recognition unit 67 analyzes a real-time image from the camera CM, and outputs the moving direction and the moving distance to the operation control unit 51 when the target component moves in the field of view. The operation control unit 51 operates the camera CM by changing the photographing direction (panning and tilting) among the photographing conditions by the same distance as the moving distance in the same direction as the moving direction. That is, according to the recognition by the recognition unit 67, the photographing field of view of the camera CM moves according to the movement of the target component.

This tracking function is typically not working. The tracking function is started, for example, in a case where a reference numeral as is added to the photographing condition PCxx (xx is a number), and is ended in a case where a reference numeral ae is added to the photographing condition PCxx. Therefore, in executing the processing according to the recipe, in a case where the operation control unit 51 recognizes that the reference numeral as is added to the photographing condition as the photographing condition corresponding to the process of the recipe, the recognition unit 67 starts analysis of the real-time image. In a case where the operation control unit 51 recognizes that the reference numeral ae is added to the photographing condition as the photographing condition corresponding to the process of the recipe, the recognition unit 67 stops the analysis of the real-time image.

### <3. Example of Photographing Condition>

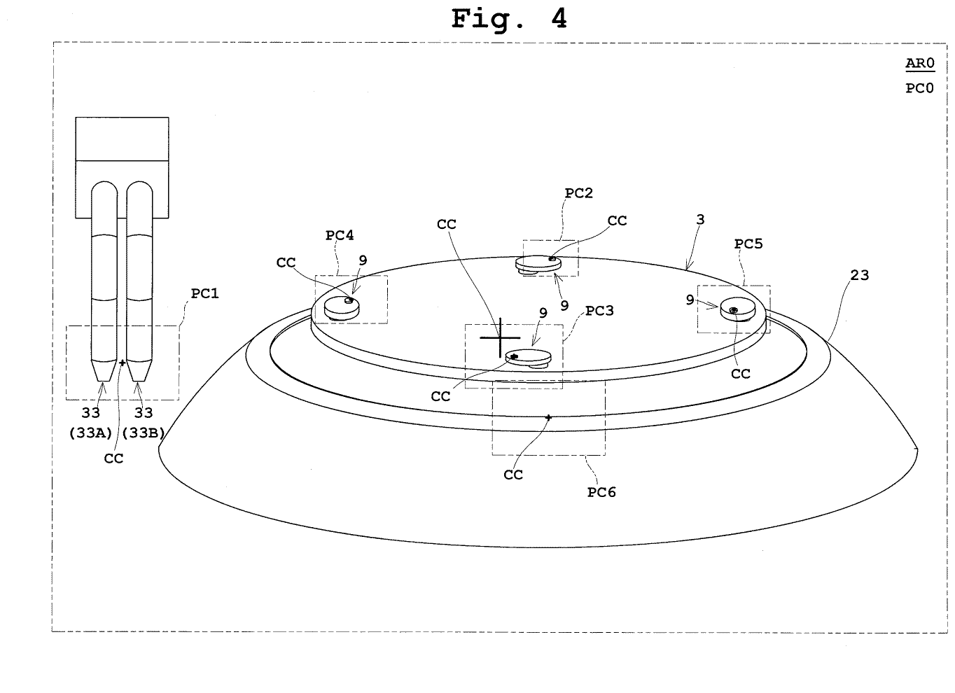

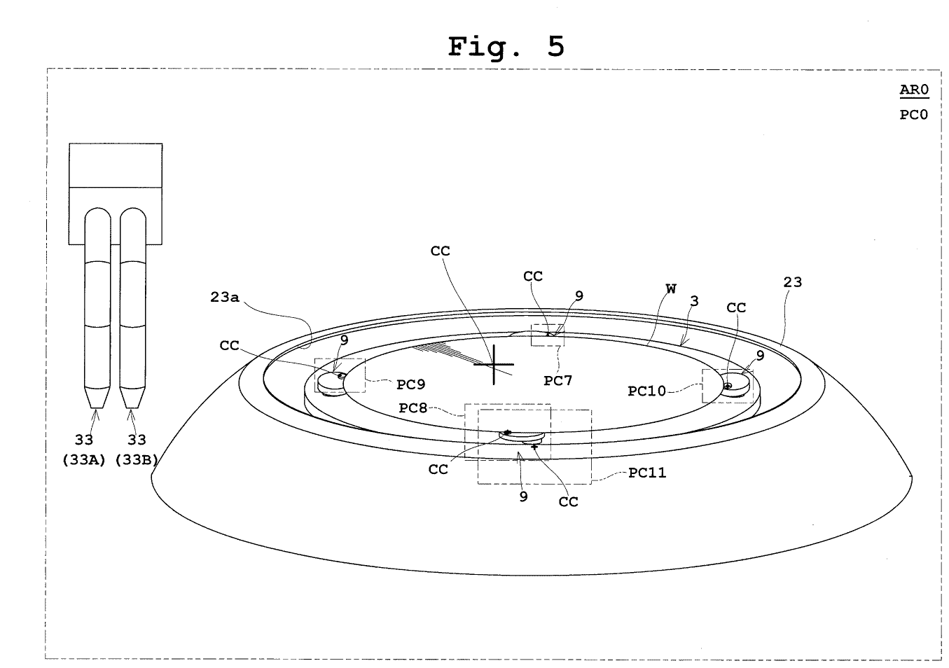

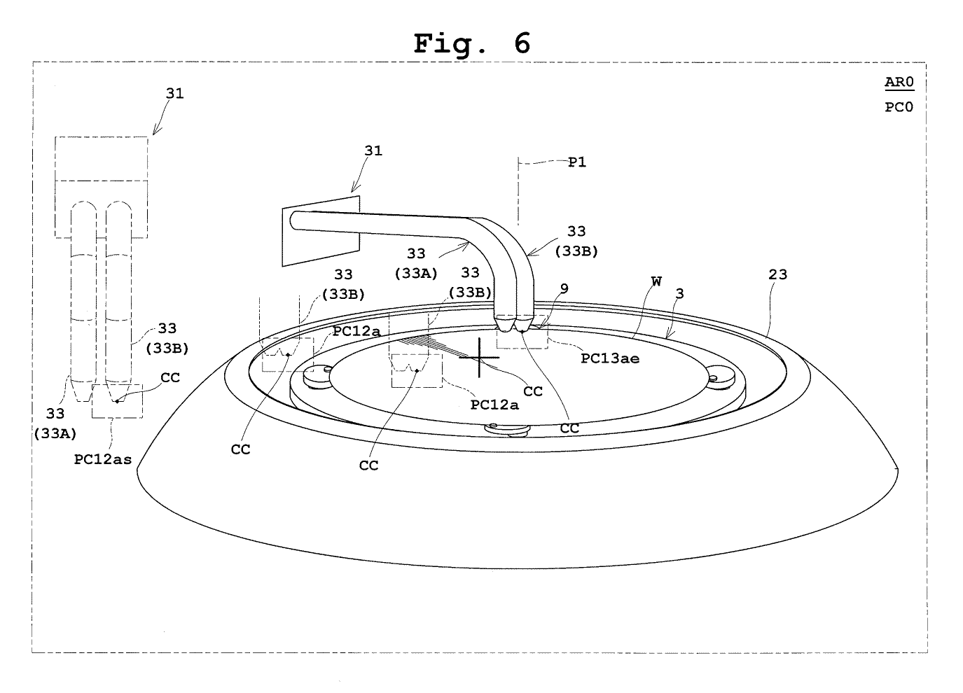

Reference is now made to FIGS. 4 to 6. FIG. 4 is a schematic view for explaining photographing conditions in the original position confirmation. FIG. 5 is a schematic view for explaining photographing conditions in the delivery confirmation and the guard confirmation. FIG. 6 is a schematic view for explaining photographing conditions in nozzle movement.

In FIGS. 4 to 6, the chucks 9 are drawn in the same size for the sake of illustration. However, in particular, in a wide-angle state in which the camera CM is the maximum field of view and the photographing magnification is the lowest, the chuck 9 on the innermost side is extremely smaller than the other chucks 9 due to the positional relationship with the camera CM, and the chuck 9 on the foremost side is the largest.

Before the substrate W is loaded, it is confirmed that the chuck 9, the guard 23, and the nozzle 33 are at the original positions. For this confirmation, for example, as illustrated in FIG. 4, photographing conditions are set.

The reference numeral AR0 represents the maximum field of view in the camera body CM1. The camera body CM1 cannot capture a wider range image. It is assumed that an image is captured under a photographing condition in which a photographing magnification of predetermined panning, tilting, and zooming is 1. It is assumed that the photographing magnification of the zooming is minimum at 1, and the larger the number, the higher the photographing magnification. The predetermined photographing condition is PC0. In the following schematic view, the photographing field of view is indicated by a two-dot chain line, and the smaller the two-dot chain line, the larger the photographing magnification of the zooming. The photographing magnifications under the following photographing conditions are all larger than 1. The adjusted photographed images obtained under the photographing conditions described below all have the same number of pixels and all have the same resolution regardless of the size of the two-dot chain line. That is, as the rectangle of the two-dot chain line is smaller, the target component is enlarged and shown.

In the case of confirming that the nozzle 33 is located at the origin position, a photographing condition PC1 is set at the confirmation required timing when the nozzle 33 is located at the origin position during the normal operation. The photographing condition PC1 is set to be smaller than the maximum field of view AR0 such that the nozzles 33A and 33B are both located within the photographing field of view.

In a case where it is confirmed that each chuck 9 is at the origin position, the following photographing conditions are set for each chuck 9 at the confirmation required timing when each chuck 9 is located at the origin position during normal operation.

Among the chucks 9, a photographing condition PC2 is set for the chuck 9 that is at the 12:00 position in FIG. 4 and is farthest from the camera CM. Since the photographing condition PC2 is the smallest when viewed in the maximum field of view AR0, the photographing magnification of the zooming is set to be the largest. A photographing condition PC3 is set for the chuck 9 closest to the camera CM at the 6 o'clock position in FIG. 4. The photographing condition PC3 has a smaller photographing magnification of zooming than the photographing condition PC2. Among the chucks 9 at the intermediate position with these chucks 9, a photographing condition PC4 is set for the chuck 9 at the 9 o'clock position in FIG. 4. In the photographing condition PC4, the photographing magnification of zooming is also about the middle between the photographing condition PC2 and the photographing condition PC3. A photographing condition PC5 is set for the chuck 9 at the 3 o'clock position in FIG. 4. In the photographing condition PC5, the photographing magnification of zooming is set to the same value as that of the photographing condition PC4, the tilting is set to substantially the same value, and the panning is set to a different value. In addition, in each of the photographing conditions PC2 to PC5, the center of the photographing field of view is set to the peripheral edge support portion 13.

In the case of confirming that the guard 23 is located at the origin position, the next photographing condition is set at the confirmation required timing when the guard 23 is located at the origin position during the normal operation.

A photographing condition PC6 is set at a position close to the camera CM in the entire guard 23. The photographing condition PC6 is set such that an edge portion of the opening 23a in the vicinity of the central portion of the guard 23 on the front side is enlarged and captured.

For example, as illustrated in FIG. 5, photographing conditions are set for the confirmation required timing at which the chuck 9 moves to the closing position during the normal operation after the substrate W is loaded and the confirmation required timing at which the guard 23 moves to the processing position during the normal operation.

In a case where it is confirmed that each chuck 9 is at the stop closing position, the following photographing conditions are set for each chuck 9 at the confirmation required timing when each chuck 9 is located at the closing position during normal operation.

Among the chucks 9, a photographing condition PC7 is set for the chuck 9 that is at the 12:00 position in FIG. 5 and is farthest from the camera CM. A photographing condition PC8 is set for the chuck 9 closest to the camera CM at the 6 o'clock position in FIG. 5. A photographing condition PC9 is set for the chuck 9 at the 9 o'clock position in FIG. 5. A photographing condition PC10 is set for the chuck 9 at the 3 o'clock position in FIG. 5. In these photographing conditions, the panning and tilting are adjusted according to the position of each chuck 9, and the photographing magnification of each zooming is increased as compared with the time of confirming the origin position. In addition, the center of the photographing field of view is set at the peripheral edge support portion 13.

In the confirmation that the guard 23 is at the processing position, the next photographing condition is set at the confirmation required timing when the guard 23 is at the processing position during the normal operation.

A photographing condition PC10 is set at a position close to the camera CM in the guard 23. The tilting of the photographing condition PC10 is adjusted according to the processing position at which the guard 23 moves up with respect to the photographing condition PC6. The photographing condition PC10 is set in the edge portion of the opening 23a in the vicinity of the central portion of the guard 23 on the front side thereof.

The photographing condition of the nozzle 33 will be described, for example, taking the nozzle 33B as an example.

In the confirmation when the nozzle 33B moves, as illustrated in FIG. 6, a photographing condition PC12as is set at the confirmation required timing when the nozzle 33B is located at the origin position during the normal operation. The photographing condition PC12as is set so that the lowermost part of the nozzle 33B can be enlarged and photographed. In addition, since the reference numeral as is added, the operation of tracking the tip portion of the nozzle 33B by the recognition unit 67 is started from this time point.

In the confirmation that the nozzle 33B has moved to the discharge position, as illustrated in FIG. 6, a photographing condition PC13ae is set at the confirmation required timing when the nozzle 33B is located at the discharge position during the normal operation. The photographing condition PC13ae is set so that the lowermost part of the nozzle 33B can be enlarged and photographed.

The tracking operation is started from the above-described photographing condition as. Therefore, between the photographing condition PC12as and the photographing condition PC13ae, a photographing condition PC12a is set at predetermined intervals to perform photographing. In the photographing condition P12a at this time, only the photographing magnification of the zooming is set to be the same as the photographing condition PC12as that is the latest photographing condition. At the time of photographing under the photographing condition PC13ae at the confirmation required timing located at the discharge position during the normal operation, the photographing is performed after moving from the immediately preceding photographing condition PC12a.

That is, the photographing field of view moves from a position closer than the confirmation required timing at which the nozzle 33B is located at the origin position. Specifically, since the movement is not the movement of the photographing field of view from the photographing condition PC12as but the movement from the last photographing condition PC12a, it is possible to quickly shift to the photographing with the photographing condition PC13ae. As a result, in the case of the target component moving like the nozzle 33, it is possible to prevent the photographing at the movement destination from being delayed.

### <4. Details of Recipe>

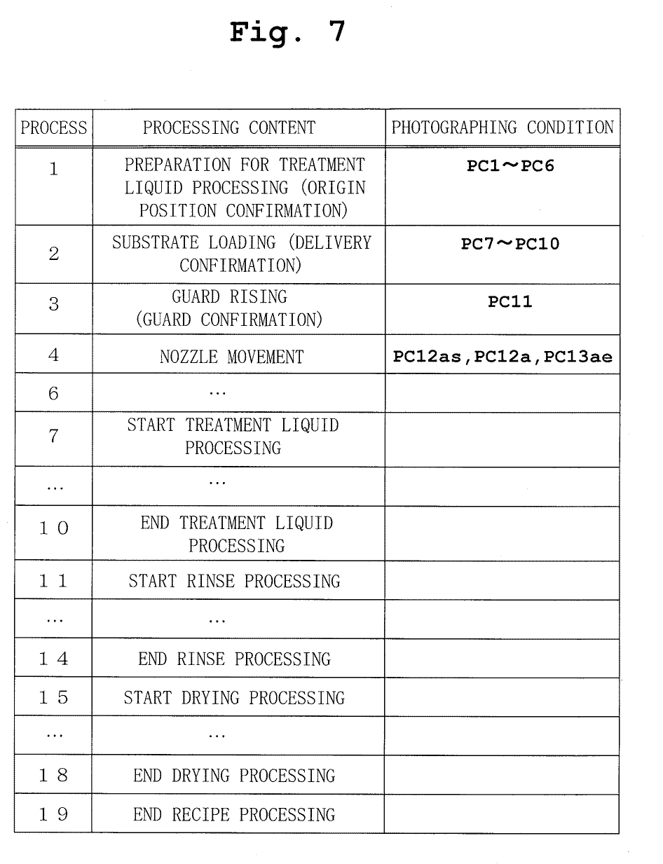

Next, FIG. 7 will be referred to. FIG. 7 is a schematic view illustrating an example of a recipe.

In this example, the recipe includes processes and processing contents. The processes define the execution order. The processing content defines what kind of operation is performed. Specifically, the processing content defines the operation content of the component. Specifically, the recipe is divided into recipe steps defining more detailed operations. Here, in order to facilitate understanding of the invention, the description of the recipe steps is omitted. In addition, detailed processing performed in the actual processing is omitted.

This recipe has, for example, the following contents. Each of the following photographing conditions is associated with each operation and confirmation required timing in each process of the recipe.

In a first process, preparation for treatment liquid processing (origin position confirmation) is executed, and the chuck 9, the guard 23, and the nozzle 33 are moved to the origin position. In a second process, the substrate W to be processed is loaded, and the acceptance is confirmed. Specifically, the chuck 9 is moved to the closing position. In a third process, guard raising is executed to move the guard 23 up to the processing position. In a fourth process, the nozzle movement is executed to move the nozzle 33 (33B) to the discharge position. In a seventh process, the treatment liquid processing is started. In a tenth process, the treatment liquid processing is terminated. In an eleventh process, the rinse processing is started. In a fourteenth process, the rinse processing is terminated. In a fifteenth process, the drying processing is started. In an eighteenth process, the drying processing is terminated. In a nineteenth process, the recipe end processing is executed.

In this recipe, the photographing conditions are set as follows. For example, in the first process, as illustrated in FIG. 4, the photographing condition PC1 is set for the nozzle 33, the photographing conditions PC2 to PC5 are set for each of the chucks 9, and the photographing condition PC6 is set for the guard 23 according to the confirmation required timing at which the chuck 9, the guard 23, and the nozzle 33 move to the origin position during the normal operation.

In the second process, as illustrated in FIG. 5, the photographing conditions PC7 to PC10 are set for each of the chucks 9 and the photographing condition PC11 is set for the guard 23 according to the confirmation required timing at which the chuck 9 moves to the closing position during the normal operation.

In the third process, the photographing condition PC11 is set as illustrated in FIG. 5 according to the confirmation required timing at which the guard 23 moves to the processing position during the normal operation.

In the fourth process, as illustrated in FIG. 6, the photographing condition PC12as and the photographing condition 13ae are set according to the confirmation required timing at which the nozzle 33 (33B) moves from the origin position during the normal operation to the discharge position during the normal operation. Tracking is performed at predetermined intervals by the photographing condition PC12as between the photographing condition PC12as and the photographing condition PC13ae.

For processes after the fourth process, description of photographing conditions is omitted in order to facilitate understanding of the invention.

### <5. Specific Example of Processing>

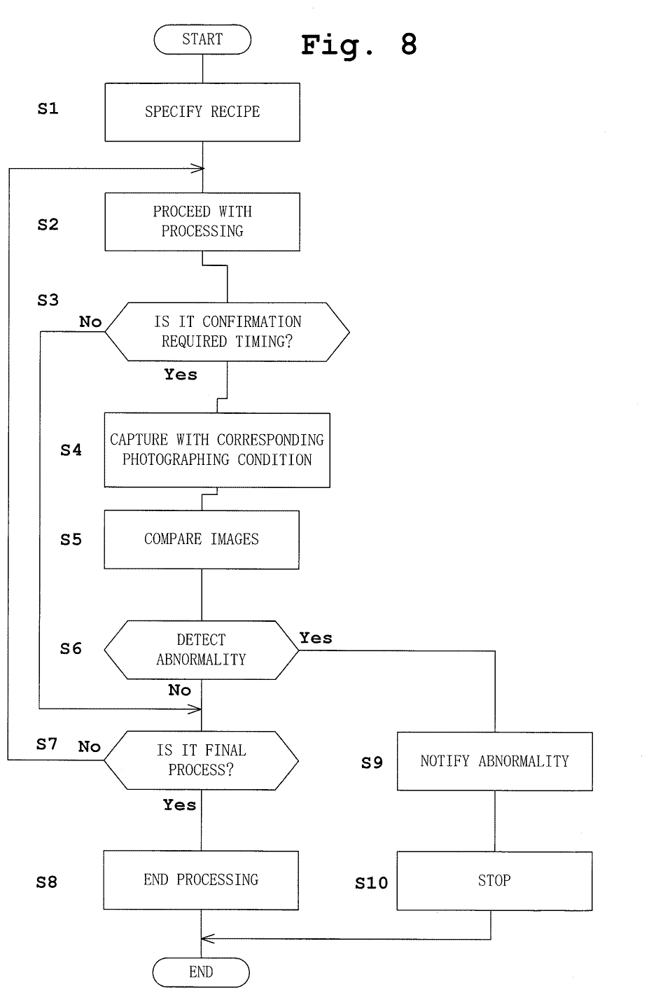

Next, a specific example of processing will be described with reference to FIG. 8. FIG. 8 is a flowchart illustrating a flow of processing in the substrate processing apparatus according to the embodiment.

### Step S1

The operator operates the instruction unit 47 to designate a desired recipe.

### Step S2

The operation control unit 51 operates each unit according to the recipe and advances the processing. For example, according to the recipe illustrated in FIG. 7, preparation for treatment liquid processing, which is the first process, is executed. Specifically, the operation control unit 51 operates the chuck drive mechanism 17, the guard moving mechanism 25, and the nozzle moving mechanism 35. Then, each of the chucks 9, the guard 23, and the nozzle 33 are moved to the origin position.

### Step S3

It is confirmed whether it is the confirmation required timing, and the processing branches. Specifically, the operation control unit 51 refers to the parameter memory 55 and checks whether there is a confirmation required timing corresponding to the process in the recipe. As illustrated in FIG. 7, in the first process, the photographing conditions PC1 to PC6 are set, and thus, there are confirmation required timing associated with the respective photographing conditions PC1 to PC6. Since there is the confirmation required timing, the process proceeds to step S4. In a case where it is not the confirmation required timing, the process proceeds to step S7.

### Step S4

The imaging is performed under the corresponding photographing condition. Specifically, the operation control unit 51 performs image capturing under the image photographing conditions PC1 to PC6 corresponding to the confirmation required timing. Here, for example, the nozzle 33 is photographed under the photographing condition PC1, each chuck 9 is photographed under the photographing conditions PC2 to PC5, and the guard 23 is sequentially photographed by the camera CM under the photographing condition PC6.

### Step S5

The images are compared. Specifically, in the image comparison unit 61, each adjusted photographed image captured by the camera CM under the photographing conditions PC1 to PC6 is compared with the corresponding normal image in the normal image storage unit 57, and the same components can be compared.

### Step S6

The process is branched depending on whether an abnormality is detected. Specifically, the abnormality detection unit 63 compares the same target components in the normal image and the adjusted photographed image, and detects an abnormality based on a difference therebetween. At this time, it is preferable to consider the allowable range of the parameter memory 55. As a result, it is possible to prevent erroneous detection of an abnormality caused by a machining error or an assembly error.

Here, it is determined that no abnormality has been detected, and the process proceeds to step S7.

Step S7 The operation control unit 51 branches the process depending on whether it is a final process of the recipe. Here, since the first process has been executed, the process returns to step S2.

### Step S2

The operation control unit 51 further advances the process according to the recipe. That is, the substrate loading which is the second process is executed. It is assumed that the substrate W to be processed is already delivered to the chuck 9 by a carrying arm (not illustrated). The operation control unit 51 operates the chuck drive mechanism 17. Then, each chuck 9 is moved to the closing position. This time point is the confirmation required timing, and as illustrated in FIG. 7, the photographing conditions PC7 to PC10 are set for each chuck 9.

### Step S3

As illustrated in FIG. 7, in the second process, since the photographing conditions PC7 to PC10 are set at each confirmation required timing, the process proceeds to step S4.

### Step S4

The operation control unit 51 performs photographing with the photographing conditions PC7 to PC10 according to the confirmation required timing. Here, for example, the camera CM sequentially performs the photographing under the photographing conditions PC7 to PC10 for each chuck 9 moved to the closing position during the normal operation.

### Steps S5 and S6

The images are compared, and the process is branched depending on whether an abnormality is detected.

Here, it is determined that no abnormality has been detected, and the process proceeds to step S7.

### Step S7

Since the operation control unit 51 has executed the second process, the process returns to step S2.

### Step S2

The operation control unit 51 further advances the process according to the recipe. That is, the guard rising that is the third process is executed. The operation control unit 51 operates the guard moving mechanism 25. Then, the guard 23 is moved to the processing position. This time point is the confirmation required timing, and as illustrated in FIG. 7, the photographing condition PC11 is set in the guard 23 in the third process.

### Step S3

In the third process, since the photographing condition PC11 is set at the confirmation required timing, the process proceeds to step S4.

### Step S4

The operation control unit 51 performs the photographing under the photographing condition PC11 corresponding to the confirmation required timing. Here, for example, the guard 23 moved upward to the processing position during the normal operation is photographed by the camera CM under the photographing condition PC11.

### Steps S5 and S6

The same target component in the adjusted photographed image and the normal image photographed in step S4 is compared, and the process branches depending on whether an abnormality is detected.

Here, it is determined that no abnormality has been detected, and the process proceeds to step S7.

Step S7 Since the operation control unit 51 has executed the third process, the process returns to step S2.

### Step S2

The operation control unit 51 further advances the process according to the recipe. That is, the nozzle movement that is the fourth process is executed. The operation control unit 51 operates the nozzle moving mechanism 35. Then, the nozzle 33 is moved to the discharge position.

### Step S3

In the fourth process, since the photographing conditions PC12as and PC13ae are set at each confirmation required timing, the process proceeds to step S4.

### Step S4

The operation control unit 51 performs the photographing under the photographing condition PC12as corresponding to the confirmation required timing. Here, for example, when the nozzle 33 (33B) is located at the origin position during the normal operation, the photographing by the camera CM is performed under the photographing condition PC12as. In addition, when the nozzle 33 (33B) is located at the discharge position during the normal operation, the photographing by the camera CM is performed under the photographing condition PC13ae. Before the nozzle 33 (33B) moves from the origin position to the discharge position, the camera CM performs tracking under the photographing condition PC12as. Therefore, when the photographing under the photographing condition PC13ae is performed at the confirmation required timing at which the nozzle 33 (33B) should be located at the discharge position, the movement of the camera CM is performed without delay.

### Steps S5 and S6

The same target component in the adjusted photographed image and the normal image photographed in step S4 is compared, and the process branches depending on whether an abnormality is detected.

Here, it is determined that no abnormality has been detected, and the process proceeds to step S7.

### Step S7

Since the operation control unit 51 has executed the fourth process, the process returns to step S2. Then, while the processing proceeds according to the recipe, each of steps S2 to S6 is executed as described above according to whether there is a confirmation required timing in each process.

Here, it is assumed that the process is the final process of the recipe in step S7. In this case, the process proceeds to step S8.

### Step S8

The operation control unit 51 takes out the treated substrate W and ends the process.

Next, a case where the abnormality detection unit 63 detects an abnormality in step S6 described above will be described.

### Step S9

The abnormality detection unit 63 operates the notification unit 45 to notify that an abnormality has occurred in the processing.

### Step S10

For example, the substrate processing apparatus 1 automatically stops processing on the substrate W. Alternatively, the operator stops the substrate processing apparatus 1 by the notification of the notification unit 45.

According to the present embodiment, when processing is performed on the substrate W according to the recipe in the housing CA, the control unit 45 causes the camera CM to acquire the adjusted photographed image. The abnormality detection unit 63 detects an abnormality of the target component based on the adjusted photographed image. The adjusted photographed image can be an image suitable for abnormality detection for each target component because the photographing condition is adjusted for each target component according to the process of the recipe. Therefore, the abnormality can be accurately detected regardless of the process of the recipe.

### <6. Other Photographing Conditions>

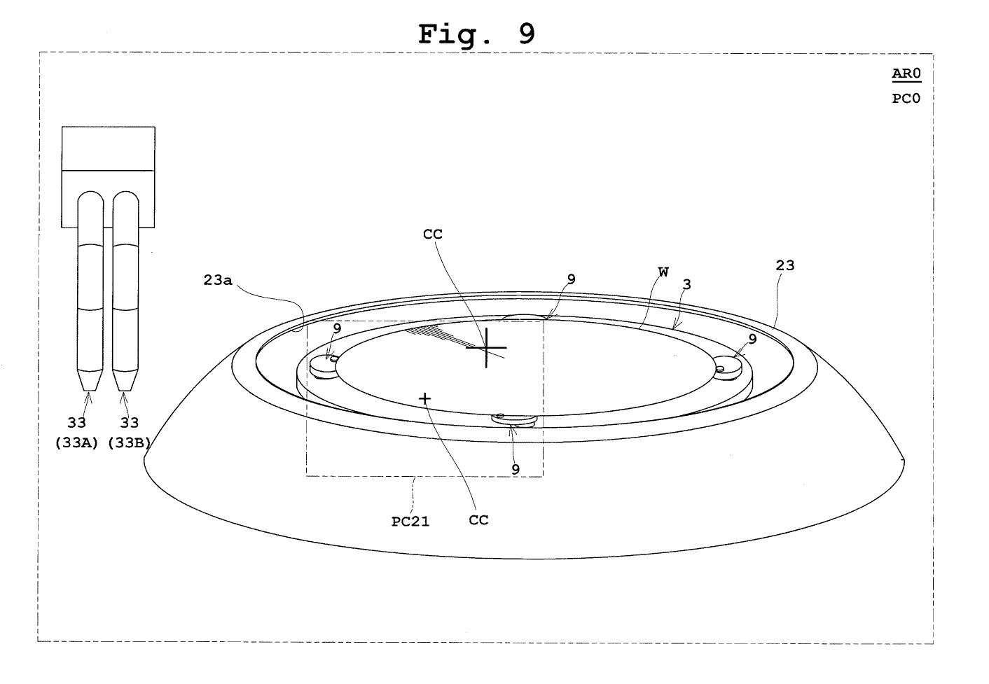

Reference is now made to FIG. 9. FIG. 9 is a schematic view for explaining another photographing condition.

In the photographing condition PC21, the chuck 9 at the 9 o'clock position and the chuck 9 at the 6 o'clock position are located in the same photographing field of view at the confirmation required timing when the chuck 9 is at the closing position during the normal operation, and the photographing field of view is minimized (maximum photographing magnification). Therefore, even in a case where a plurality of target components are imaged as described above, a resolution sufficient for abnormality detection can be obtained for each target component. In the photographing condition PC21, the photographing field of view may be set so as to slightly include the periphery of the target component.

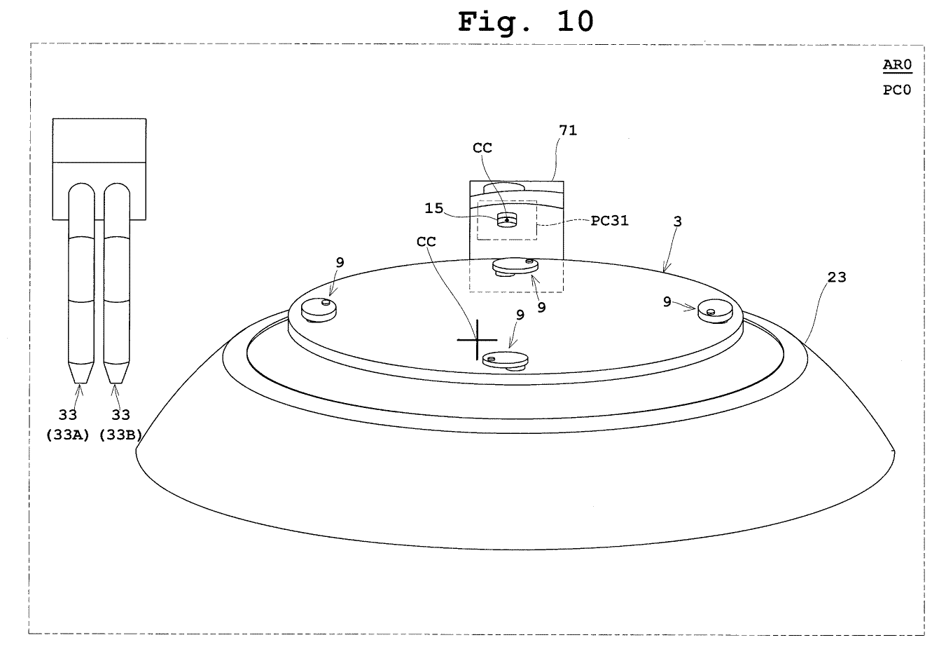

Reference is now made to FIG. 10. FIG. 10 is a schematic view for explaining photographing conditions in a case where a mirror is used.

A mirror 71 has a function of reflecting light. The mirror 71 is disposed at a position facing the camera CM and facing the camera CM, and reflects the rotating magnet 15 in a blind spot from the camera CM toward the camera CM. For example, the mirror 71 is disposed on the far inside of the chuck 9 at the 12 o'clock position. The mirror 71 is disposed slightly upward such that the reflecting surface faces the camera CM. In this case, the photographing condition PC31 is set. For example, the photographing condition PC31 is set such that a portion where the rotating magnet 15 arranged on the lower surface side of the spin chuck 3 is projected on the mirror 71 is positioned in the photographing field of view.

According to such a configuration, in the camera CM, the rotating magnet 15 on the lower surface of the spin chuck 3 in a blind spot can be photographed by the mirror 71. Therefore, the abnormality of the target component in a blind spot can be detected without increasing the number of cameras CM. As a result, the device cost can be suppressed.

The correspondence between the above-described embodiments and the present invention is as follows.

The inside of the housing CA corresponds to a “processing unit” in the present invention. The camera CM corresponds to a “photographing unit” in the present invention. The parameter memory 55 corresponds to a “photographing condition storage unit” in the present invention. Step S2 corresponds to a “processing step” in the present invention. Step S4 corresponds to a “photographing step” in the present invention. Step S6 corresponds to an “abnormality detection step” in the present invention.

### <7. Substrate Processing System>

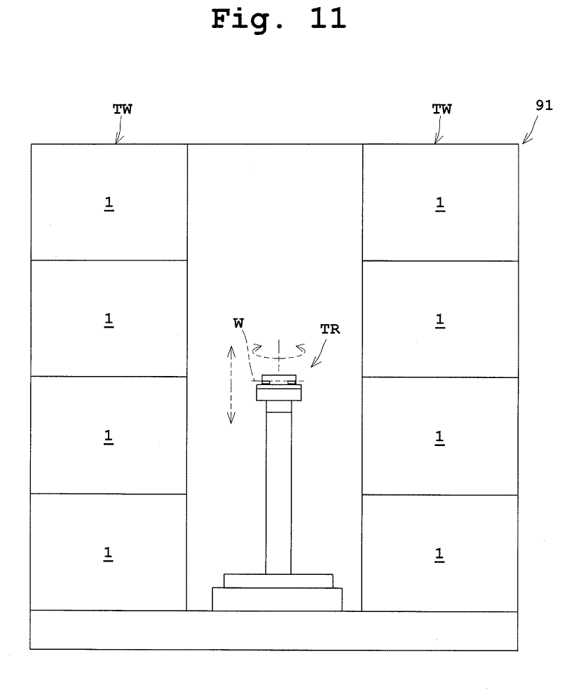

The above-described embodiment is a configuration of the substrate processing apparatus 1 alone, but the present invention can also be applied to the following configuration. Reference is now made to FIG. 11. FIG. 11 is a schematic view of a substrate processing system according to an embodiment.

The substrate processing system 91 includes the above-described substrate processing apparatus 1 in a stacked manner. The substrate processing system 91 includes, for example, a tower TW including four stages of the substrate processing apparatuses 1 in the height direction. The substrate processing system 91 is arranged to face the tower TW with a space therebetween. In the substrate processing system 91, a transfer robot TR is disposed between the towers TW. The transfer robot TR is configured to be movable up and down in the height direction. The transfer robot TR is configured such that an arm (not illustrated) can move forward and backward with respect to the substrate processing apparatus 1. The transfer robot TR transfers the substrate W to and from each substrate processing apparatus 1. Even in such a substrate processing system 91, the above-described effects are obtained in each substrate processing apparatus 1.

The substrate processing system 91 may include, for example, a camera that places the transfer robot TR in the field of view. Then, as described above, it is preferable that the abnormality detection is set to be performed by the unique photographing condition at the confirmation required timing set to the origin position or the delivery position of the transfer robot TR, and the arm (not illustrated) on which the substrate W is placed is set as the target component. As a result, it is possible to detect an abnormality related to deformation of the arm of the transfer robot TR, an abnormality of the moving speed, an abnormality of the drive system, and the like.

The present invention is not limited to the above embodiment, and can be modified as follows.

(1) In the above-described embodiment, the camera CM is disposed on the ceiling surface of the housing CA. However, the present invention does not limit the arrangement position of the camera CM to this position. For example, the camera CM may be attached to the side surface of the housing CA. In addition, the camera CM may be attached to the extending portion 33a of the nozzle 33. As a result, it is possible to photograph a target component that cannot be photographed by the fixedly arranged camera CM, and thus, it is possible to reduce a blind spot. In addition, a configuration may be adopted in which the camera CM is not attached to the nozzle 33, a dedicated arm is provided, and the camera CM is moved to a position where the target component can be easily photographed according to the recipe. The dedicated arm preferably includes a turning mechanism and an expansion/contraction mechanism. This can minimize blind spots.

(2) In the above-described embodiment, the movement of the guard 23, the discharge of the treatment liquid from the nozzle 33, and the abnormality detection of the operation of the chuck 9 have been described as examples. However, the present invention is not limited to such detection. Since any component that can be photographed by the camera CM can be a target component, abnormality detection may be performed using, for example, an operation shaft of the air cylinder 27, an on-off valve, or the like as the target component.

(3) In the above-described embodiment, photographing conditions are stored in advance in the parameter memory 55. However, the present invention is not limited to such a configuration. For example, in the recipe memory 53, the photographing condition may be directly associated with each process of the recipe and stored.

(4) In the above-described embodiment, the substrate processing apparatus 1 that processes the substrate W with the treatment liquid has been described as an example. However, the present invention is not limited to the substrate processing apparatus having such a configuration. For example, the present invention can also be applied to a device for heat-treating the substrate W, a device for transporting the substrate W, a device for exposing the substrate W, and the like. In addition, the present invention is not limited to the single wafer type apparatus that processes the substrates W one by one as described in the embodiment. That is, the present invention can also be applied to a batch type apparatus that simultaneously processes a plurality of substrates.

### REFERENCE SIGNS LIST

1 substrate processing apparatus
CA housing
W substrate
3 spin chuck
P1 to P3 rotation center
9 chuck
11 lower surface support portion
13 peripheral edge support portion
17 chuck drive mechanism
Z1, Z2, Z3 origin sensor
23 guard
23a opening
25 guard moving mechanism
31 treatment liquid supply mechanism
33, 33A, 33B nozzle
35 nozzle moving mechanism
CM camera
CM1 camera body
CM2 camera moving mechanism
C1, C2 rotation center
C2 rotation center
AR0 maximum field of view
45 control unit
49 notification unit
51 operation control unit
53 recipe memory
55 parameter memory
57 normal image storage unit
59 image processing unit
61 image comparison unit
63 abnormality detection unit
PC0 to PC11, PC12as, PC13ae, PC21, PC31 photographing condition
71 mirror

1. A substrate processing apparatus that performs predetermined processing on a substrate, the substrate processing apparatus comprising:
a processing unit configured to process a substrate;
a photographing unit configured to image a target component that is an abnormality detection target among components constituting the processing unit, the photographing unit being capable of adjusting photographing conditions of a photographing direction of panning for moving a photographing field of view in a horizontal direction and tilting for moving a photographing field of view in a vertical direction, and a photographing magnification of zooming for expanding and contracting the photographing field of view;
a control unit configured to, when processing is performed by the processing unit according to a recipe defining processing contents of a substrate, cause the photographing unit to capture an image by adjusting the photographing condition for each target component according to a process of the recipe, and cause the photographing unit to acquire an adjusted photographed image; and
an abnormality detection unit configured to detect an abnormality of the target component based on the adjusted photographed image.

2. The substrate processing apparatus according to claim 1, further comprising
a photographing condition storage unit configured to store the photographing condition in advance for each process of the recipe, wherein
the control unit causes photographing to be performed based on the photographing condition.

3. The substrate processing apparatus according to claim 1, further comprising
a recognition unit configured to recognize a specific target component projected in a photographed image captured by the photographing unit, wherein
the control unit adjusts the photographing direction in such a way to track the specific target component according to a recognition result of the recognition unit.

4. The substrate processing apparatus according to claim 1, wherein in the photographing condition, the photographing magnification is set to a maximum magnification so as to minimize the photographing field of view in a case where a plurality of the target components fall within a photographing field of view of the photographing unit.

5. The substrate processing apparatus according to claim 1, further comprising
a mirror disposed at a position facing the photographing unit and facing the photographing unit, and configured to reflect the target component in a blind spot from the photographing unit toward the photographing unit, wherein
the photographing unit captures an image of the target component in a blind spot via the mirror.

6. A substrate processing system comprising a plurality of the substrate processing apparatuses according to claim 1.

7. A substrate processing method for performing predetermined processing on a substrate, the substrate processing method comprising:
a processing step of processing a substrate by a processing unit according to a recipe defining processing contents of the substrate;
a photographing step of causing the photographing unit to capture an image by adjusting the photographing condition for each target component according to a process of the recipe, the photographing unit being capable of adjusting photographing conditions of a photographing direction of panning for moving a photographing field of view in a horizontal direction and tilting for moving a photographing field of view in a vertical direction and a photographing magnification of zooming for expanding and contracting a photographing field of view, and causing the photographing unit to acquire an adjusted photographed image; and
an abnormality detection step of detecting an abnormality of the target component based on the adjusted photographed image.
